(19) United States
(12) Patent Application Publication
(10) Pub. No.: US 2007/0120164 A1
(43) Pub. Date: May 31, 2007

(54) FILM FORMING METHOD AND OXIDE THIN FILM ELEMENT

(75) Inventors: TETSURO FUKUI, Yokohama-shi (JP); KENICHI TAKEDA, Yokohama-shi (JP); TAKANORI MATSUDA, Tokyo (JP); HIROSHI FUNAKUBO, Yokohama-shi (JP); SHINTARO YOKOYAMA, Yokohama-shi (JP)

Correspondence Address: FITZPATRICK CELLA HARPER & SCINTO, 30 ROCKEFELLER PLAZA, NEW YORK, NY, 10112, US

(73) Assignees: CANON KABUSHIKI KAISHA, Tokyo (JP); TOKYO INSTITUTE OF TECHNOLOGY, Tokyo (JP)

(21) Appl. No.: 11/551,122

(22) Filed: Oct. 19, 2006

(30) Foreign Application Priority Data
Oct. 20, 2005 (JP) 2005-305814

(51) Int. Cl. H01L 29/94

(52) U.S. Cl. 257/295

(57) ABSTRACT

The invention provides a method of forming, on a substrate, a thin film of a perovskite type oxide in which at least either of a site A and a site B is constituted of plural elements and the plural elements in at least either site include elements different in valence number within such site, the method including steps of dividing the elements belonging to the site A and the site B in plural groups in such a manner that the elements different in valence number belong to a same group, and supplying the substrate with raw materials containing the elements belonging to such respective groups in respectively different steps.

### BACKGROUND OF THE INVENTION

1. Field of the Invention

The present invention relates to a method of forming a thin film of a perovskite type oxide, containing plural elements constituting at least either of site A and site B, and an oxide thin film element including a perovskite type oxide thin film formed by the film forming method.

2. Description of the Related Art

Recently, developments are being actively conducted in ferroelectric thin films for the application to an ferroelectric RAM (also represented as FeRAM), and in ferroelectric thin films and piezoelectric/electrostric thin films for the application to an optical shutter and a piezoelectric actuator. Among these, various metal oxides having a layer-structured structure have been reported as materials having a large ferroelectric property (for example cf. Non-Patent Reference 1). Among these, Ruddelsdon-Popper type oxides, layer-structured compounds, tungsten-bronze compounds and ABO₃ perovskite oxides are attracting attention, including the application to FeRAM. However, a film forming method capable of obtaining a thin film of satisfactory crystallinity has not yet been established, as the number of elements and the composition thereof are diversified. For this reason, there has been desired a method of reproducibly forming an oxide thin film, containing plural elements as the site A element or the site B element and showing a high crystallinity.

Non-Patent Reference: Hiroshi Ishihara (editor), “New Development in Ferroelectric Memory”, p. 3-5, CMC Press, Japan, published Feb. 26, 2004.

### SUMMARY OF THE INVENTION

Therefore, an object of the present invention is to provide a method of reproducibly forming a thin film of a perovskite type oxide of satisfactory crystallinity, containing plural elements constituting at least either of the site A and the site B, without a different phase such as a pyrochlore phase. Another object is to provide an oxide film with a satisfactory breakdown voltage. Still another object of the present invention is to provide a perovskite type oxide thin film formed by such film forming method, and an oxide thin film element formed by such oxide thin film and having a large piezoelectric property.

The aforementioned objects can be accomplished by the film forming method of the present invention, for forming, on a substrate, a thin film of a perovskite type oxide in which at least either of the site A and the site B is constituted of plural elements and the plural elements in at least either site include elements different in valence number within such site, wherein the elements belonging to the site A and the site B are divided in plural groups in such a manner that the elements different in valence number belong to a same group, and raw materials containing the elements belonging to such respective groups are supplied in respectively different steps onto the substrate. Also the aforementioned objects can be accomplished by a thin film of perovskite type oxide formed by the film forming method of the present invention. Furthermore, the aforementioned objects can be accomplished by an oxide thin film element of the present invention, including a piezoelectric member having a thin film of the invention, and a pair of electrodes in contact with the piezoelectric member.

The film forming method of the present invention allows to obtain a single-crystalline thin film, a mono-oriented crystal thin film or a polycrystalline thin film of a perovskite type oxide with a satisfactory crystallinity, even in a composition which is liable to include a pyrochlore phase or an amorphous portion. In particular, the present invention is suitable for forming a perovskite type oxide thin film of a Ruddelsdon-Popper type oxide, a Bi layer-structured compound, or a tungsten bronze compound. It is particularly suitable for forming an ABO₃ type perovskite thin film.

Also an oxide thin film element having a large piezoelectric property, by including a piezoelectric member formed by a perovskite type oxide thin film which is obtained by the film forming method above.

Further features of the present invention will become apparent from the following description of exemplary embodiments with reference to the attached drawings.

### BRIEF DESCRIPTION OF THE DRAWINGS

FIG. 1 is a view showing a raw material supply method in an embodiment of the film forming method, utilizing an MO-CVD process of the present invention.

FIG. 2 is a view showing an example of a film forming method, utilizing a prior sol-gel or MOD process.

FIG. 3 is a view showing an example of a film forming method, utilizing a prior sol-gel or MOD process of the present invention.

FIG. 4 is a view showing an example of a film forming method, utilizing a prior sol-gel or MOD process of the present invention.

FIG. 5 is a schematic view showing an embodiment of an oxide thin film element of the present invention.

### DESCRIPTION OF THE EMBODIMENTS

In the following, the present invention will be clarified in detail.

The film forming method of the present invention is a method for forming, on a substrate, a thin film of a perovskite type oxide containing plural elements constituting at least either of the site A and the site B wherein the elements are different in valence number in at least a part. In the method, the elements belonging to the site A and the site B are divided in plural groups, and raw materials containing the elements belonging to such respective groups are supplied in respectively different steps onto the substrate. In the group as used in the present invention, at least an element is to be selected. The method of the invention includes plural steps of supplying the substrate with the raw materials containing the aforementioned elements, and the steps each may be repeated in two or more plural steps.

Now explanation will be made on an example of a perovskite type oxide thin film, having a composition represented by (A₁, A₂, . . . , Aₙ) (B₁, B₂. . . ., Bₘ) Oₓ. Since plural elements are contained in at least either of the elements (A₁, A₂, . . . , Aₙ) constituting the site A and those (B₁, B₂, . . . , Bₘ) constituting the site B, at least either of the suffix n for the site A and the suffix m for the site B is 2 or larger.

Now, there will be shown an example of forming a perovskite type oxide thin film, represented by n=2 and m=2. For example, the elements of the site A and the site B mentioned above are divided into a group I [A₁] and a group II [A₂, B₁, B₂]. The step of supplying the raw material of the element of the group I onto the substrate, and the step of supplying the raw materials of the elements of the group II onto the substrate are provided in different process steps. It is also possible to divide the elements into three groups of a group I [A₁], a group II [A₂, B₁] and a group III [B₂] and to supply the substrate with these groups in respectively different process steps, and the combination is not restricted to that described above.

Also in the case that the site A contains plural elements [A₁, A₂, . . . , Aₙ], it is preferable to execute the grouping in such a manner that the elements of the site A are contained in plural groups. More specifically, there are at least included a step I of supplying the substrate with a raw material for at least an element among the elements of the site A, and a step II of supplying the substrate with a raw material for other elements of the site A and a raw material for the element of the site B. The step II may be further divided into plural steps, but it is preferable to simultaneously supply the substrate with a raw material of at least an element of the site A and with a raw material of at least an element of the site B.

Now there will be shown a specific example. In a case of forming a thin film of a perovskite type oxide of a composition (Bi_{3.25}La_{0.75})Ti₃O₁₂ as represented by (A₁, A₂)B₁Oₓ, it is preferable to divide A₁ and A₂ into different groups, and such groups are supplied to the substrate in respectively different steps. More specifically, the elements are divided into a group I [element A₁ which is Bi: bismuth] and a group II [element A₂ which is La: lanthanum and element B₁ which is Ti: titanium]. There are executed a step I of supplying the substrate with a material containing the element of the group I, and a step II of supplying the substrate with materials containing the elements of the group II, and such steps are preferably executed alternately, with a certain non-supply period in between. Such method allows to form a satisfactory thin film of a perovskite oxide crystal, thus providing a film of a high breakdown voltage.

Also there will be explained a case of forming a thin film of a perovskite type oxide of a composition for example of Sr_{0.8}Bi_{2.2}Ta₂O₉. In such case, the elements are divided into a group I [element A₂ which is Bi: bismuth] and a group II [element A₁ which is Sr: strontium, and element B₁ which is Ta: tantalum], and such groups are supplied to the substrate in respectively different steps.

In the foregoing, there has been explained a case where the site A has plural elements, and, in case the site B has plural elements, such plural elements of the site B may be divided in such a manner that such plural elements belong to plural groups.

Now there will be explained a film forming method in the case that the plural elements, belonging to at least either site, include elements of different valence number.

In such case, it is preferable, when dividing the elements of the sites A and B into plural groups, that the elements having different valence numbers within a same site belong to a same group.

Now there will be explained, as an example, a case of a thin film of perovskite type oxide, represented by (A₁, A₂) (B₁, B₂)Oₓ in which the elements A₁ and A₂ have different valence numbers.

The elements A₁ and A₂ preferably belong to a same group, and the elements are divided into a group I [A₁, A₂] and a group II [B₁, B₂] which are supplied to the substrate in different steps. The group II [B₁, B₂] may be further divided for example as a group [B₁] and a group [B₂]. Also the grouping may be executed as a group I [A₁, A₂, B₁ (or B₂)] and a group II [B₁ (or B₂)]. In the foregoing, there has been shown an example in which the elements of the site A have different valence numbers, but the process may be executed in a similar manner when the elements of the site B have different valence numbers. Also the site A and/or the site B may include three or more elements.

Now a specific example will be explained. In the case that the elements within a site have different valence numbers, an electrical neutrality is attained with oxygen ions in general by a compositional proportion of the elements. For example in case of Pb(Znₓ, Nb₁₋ₓ)O₃ represented by A₁(B₁, B₂)O₂, Zn constituting the element B₁ is divalent while Nb constituting the element B₂ is pentavalent, and Pb constituting the element A₁ is divalent (2+), so that the site B preferably become tetravalent (4+) in the combination of Zn and Nb. For this reason, x in the aforementioned formula is preferably ⅓. In case of x=3, the elements of the site B become tetravalent (4+). In combination with Pb constituting the element of the site A, the valence number becomes 6+, which provides an electrical neutrality with 6−of O₃, thus improving the breakdown voltage of the film. On the other hand, in the case that Zn of the element B₁ and Nb of the element B₂ are divided in different groups and supplied to the substrate in different steps, such elements tend to be incorporated in the site B according to the supplied amounts, thereby providing an electrically non-neutral film, with a low breakdown voltage.

In the producing method of the present invention, the elements of different valence numbers (Zn and Nb in the above example) are simultaneously supplied to ensure an electrical neutrality, with introductions at a proportion of Zn at 1 atom mol and Nb at 2 atom mol, thereby providing an electrically neutral film with a high breakdown voltage.

Also in case of utilizing Pb or Bi which is easily diffusible, it is preferable to supply such element in excess of the composition of the film.

In case of another example of forming a film of Pb(Zr, Ti, Nb)O₃ represented by A₁(B₁, B₂, B₃)O₃, since Zr and Ti are tetravalent while Nb is pentavalent, the elements are divided into a group I [Pb constituting the element A₁, and Ti constituting the element B₂], and a group II [Zr constituting the element B₁, and Nb constituting the element B₃]. The division may also be executed into a group I [Pb, Zr] and a group II [Ti, Nb], or into a group I [Pb] and a group II [Zr, Ti, Nb], and the raw materials containing the elements of the respective groups may be respectively supplied in different steps to the substrate.

As explained above, the element ratio has to be controlled in order to obtain a neutral film of a high breakdown voltage. A severer control of the element ratio is required particularly in the case that plural elements of different valence numbers are contained in a same site, the groups is preferably so made that the elements with different valence numbers of a same site belong to a same group. It is rendered possible, in this manner, to control the ratio of the simultaneously supplied elements, thereby enabling to form a neutral film with a high breakdown voltage.

The film forming method of the present invention is different from a method, as in the case of forming a thin film of Pb(Zr, Ti)O₃, of forming layers of different compositions, utilizing a PbTiO₃ layer as an anchor layer. The method of the present invention, as explained above, supplies the grouped raw materials in different steps, thereby supplying the raw materials on time-shared basis and obtaining an integral thin film. The raw material supply is executed in plural steps on time-shared basis, because a single raw material supply cannot provide a thin film of a satisfactory quality when the film has a large thickness. In contrast, when the raw material supply is divided into plural steps, on time-shared basis for example in alternate supplies, the thin films formed by the respective raw materials are integrated to provide a thin film of a satisfactory crystallinity. For this purpose, the film thickness formed by a single supply step is preferably as small as possible, and is 10 nm or less and more preferably 3 nm or less. Also in order that the film formed by plural supply steps constitutes a uniform film as a whole, the film formation may be executed under heating of the substrate or a heating step may be executed after each film forming step. A specific substrate temperature will be explained later, but a heating of the substrate causes diffusion of the elements within the plural films formed on the substrate, thereby forming a uniform film as a whole. In this manner it is possible not only to suppress an unexpected reaction among the raw materials at the supply thereof but also to obtain a thin film of a satisfactory crystallinity.

The perovskite type oxide thin film, obtained by the film forming method of the present invention, preferably has a film thickness of from 50 nm to 10 μm, and is advantageously usable as a dielectric member, a piezoelectric member, a pyroelectric member or a ferroelectric member.

The film forming method of the present invention allows to form a perovskite type oxide thin film such as a Ruddelsdon-Popper type oxide thin film, a Bi layer-structured compound thin film, a tungsten bronze type oxide thin film and the like.

The Bi layer-structured compound above is a compound represented by a general formula (Bi₂O₂) (A_{S-1}B_{S}O_{3S+1}) (wherein S represents an arbitrary integer of 2 or larger). The film forming method of the present invention is suitable for forming a film of a Bi layer-structured compound, containing plural elements as the element A and/or the element B above. Also the Ruddelsdon-Popper type oxide is a compound represented by a general formula (AO) (A_{S-1}B_{S}O_{3S+1}) (wherein S represents an arbitrary integer of 2 or larger). This oxide has a structure in which a rock salt face represented by AO is inserted between perovskite type structures represented by (ABO₃)_{S}. The film forming method of the present invention is advantageous also in the oxide thin film of this type, containing plural elements as A and/or B.

The tungsten bronze type oxide above is a compound represented by a general formula A_{f}B₅O₁₅ (wherein f is an arbitrary positive integer). The element of site A may be Mg, Ca, Ba, Sr, Pb, K, Na, Li, Rb, Tl, Bi, Cd or a rare earth element. The element of site B may be Ti, Zr, Ta, Nb, Mo, W. Fe or Ni. The film forming method of the present invention is also advantageous for such compound thin film, containing plural elements at least in the site A or in the site B.

The film forming method of the present invention may utilizing a metalorganic chemical vapor deposition process (also represented as MO-CVD), a sol-gel process or a metalorganic compound deposition process (also represented as MOD). Among these, MO-CVD process is preferred.

The MOD process employs a raw material different from that for the sol-gel process, but the film forming process itself is same. The MOD process is a film forming process including a coating step of coating a raw material solution on a substrate, a drying step of drying the coated raw material solution, a preliminary heating step of preliminarily heating the raw material film obtained by drying, and a crystallization step of firing an oxide, obtained by the preliminary heating, thereby causing crystallization. In case of forming a multi-layered film, these steps are repeated for forming each layer. The raw material to be employed in the MOD process has to be dissolved, and is therefore required to have a high solubility. It is also preferable to execute all the raw material supply steps at least once, before entering the preliminary heating step.

In the present invention, the MOD process is as useful as the sol-gel process.

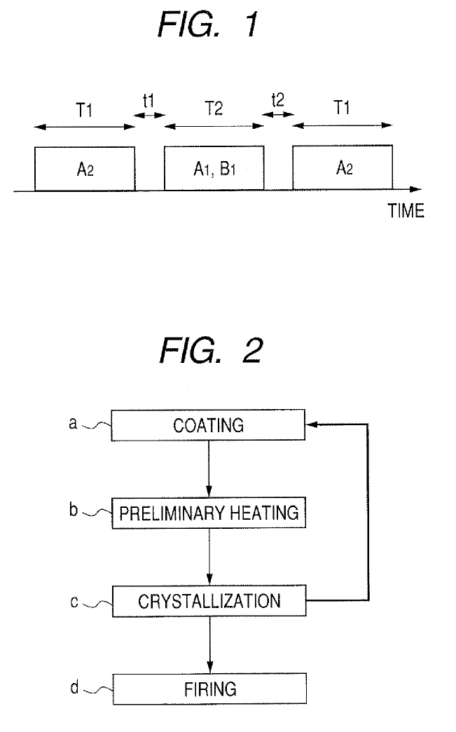

FIG. 1 shows an embodiment of the film forming method of the present invention, utilizing the MO-CVD process. In case of forming a thin film of a composition Sr_{0.8}Bi_{2.2}Ta₂O₉ represented by (A₁, A₂)B₁Oₓ, at first a raw material gas for bismuth (Bi) as the element A₂ is supplied to the substrate, and then raw material gases for strontium (Sr) as the element A₁ and for tantalum (Ta) as the element B₁ are simultaneously supplied to the substrate. The film thickness can be controlled by repeating these steps. The substrate is preferably heated at the raw material supply. Also as shown in FIG. 1, no-supply times (t1, t2) of interrupting the raw material supply for a predetermined period are preferably provided between the raw material supply steps, in view of improving the crystallinity and the density of the obtained thin film. The duration of t1 and t2 may be same or different. The duration of t1, t2 is preferably from 1 to 100 seconds, and more preferably from 2 to 60 seconds. It is preferable to include oxygen gas at the raw material supply. The partial pressure of oxygen is generally selected as from 66 Pa to 6.7 kPa, preferably from 130 Pa to 2.7 kPa. In addition to oxygen gas, an inert gas such as argon gas, nitrogen gas or neon gas may also be introduced. The raw material supply time (T1, T2) is preferably selected as from 1 to 200 seconds, and more preferably from 5 to 100 seconds. FIG. 1 shows an embodiment in which two different raw material supply steps are repeated, but there may also be adopted an embodiment in which three or more different raw material supply steps are repeated. Repetition of such steps allows to easily form a perovskite type oxide thin film, having a film thickness of 1 μm or larger. The supply amounts of the raw material gases may be regulated by the raw material supply time (T1, T2) in each raw material supply step, the raw material concentrations and a number of repetition of the raw material supply steps.

In the present invention, as explained above, the film formation is preferably conducted by heating the substrate and supplying the raw material onto the heated substrate. In case of utilizing the sol-gel process or the MOD process, the heating temperature is generally 50° C. or higher and preferably 100° C. or higher, and the heating temperature is generally 400° C. or lower and preferably 200° C. or lower. Also in case of utilizing the MO-CVD process, the heating temperature is generally 200° C. or higher and preferably 400° C. or higher, and the heating temperature is generally 850° C. or lower and preferably 750° C. or lower.

Now there will be explained film forming steps, in an example of a prior film forming method utilizing the sol-gel process or the MOD process, with reference to FIG. 2. In the example of the prior film forming method shown in FIG. 2, for example in case of forming a film of lead zirconate-niobate-titanate (also represented as PZNT), a solution containing all the raw materials for Pb, Zr, Nb and Ti is prepared and is coated for example by a spin coater. Then it is preliminarily heated to eliminate the organic component, and is fired at a temperature higher than the preliminary heating temperature to cause crystallization, thereby obtaining a crystalline PZNT thin film. This operation is repeated for obtaining a thin film of a predetermined thickness.

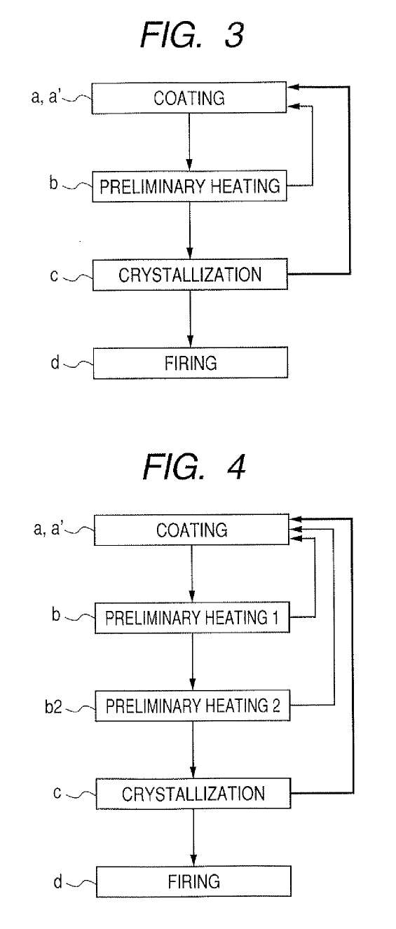

On the other hand, an embodiment of the film forming method of the present invention, utilizing the sol-gel process or the MOD process, will be explained with reference to FIGS. 3 and 4.

In the embodiment shown in FIG. 3, for example in case of forming a PZNT thin film, a liquid containing the raw materials for Pb and Ti is coated in a coating step a, and it is preliminarily heated in a preliminary heating step (b). Then a liquid containing the raw materials for Zr and Nb is coated in a coating step a′, and it is preliminarily heated in a preliminary heating step (b). After these steps are repeated plural times, a crystallization step (c) executes a heating at a temperature equal to or higher than that in the preliminary heating step, thereby causing crystallization. These steps are repeated plural times if desired, and a firing step (d) executes a firing process at a temperature equal to or higher than that in the crystallization step (c), thereby obtaining a PZNT thin film having a predetermined film thickness. In this case, Zr is tetravalent while Nb is pentavalent, so that Zr and Nb, different in valence number, are to be supplied simultaneously, and separately from Ti.

In an embodiment shown in FIG. 4, in a similar manner as the embodiment shown in FIG. 3, a liquid containing the raw materials for Pb and Ti is coated in a coating step a and preliminarily heated, and a liquid containing the raw materials for Zr and Nb is coated thereon in a coating step a′ and preliminarily heated. A preliminary heating step b is preferably executed after each coating step. After these steps are repeated plural times, a further preliminary heating is executed in a preliminary heating step b2. If desired, these steps are repeated plural times. Thereafter, a crystallization step c executes a heating at a temperature higher than that in the preliminary heating step b2 to cause crystallization. If desired, these steps may further be repeated plural times. The embodiment of the present invention shown in FIG. 3 or 4 is different from the prior example shown in FIG. 2, in including a step of supplying at least one of the raw materials for the elements of site A (or elements of site B), separately from the raw materials for other elements of the site A or site B, onto the substrate.

The coating steps a and a′ may utilize various coating methods such as spin coating, curtain coating, dip coating, roll coating or die coating. Preferred is spin coating method that is capable of forming a thin film. In the case that the film formation is executed by a sol-gel process or an MOD process, the substrate need not be heated at the coating, because, in these film forming processes, the crystallinity can be controlled in the preliminary heating step b or b2, or in the crystallization step c.

In the preliminary heating step b or b2, the preliminary heating is carried out at a temperature ordinarily of 300° C. or higher, preferably 350° C. or higher, and at a temperature ordinarily of 550° C. or lower, preferably 450° C. or lower. A preliminary heating temperature of 300° C. or higher allows to easily remove the organic component. Also a preliminary heating temperature of 550° C. or lower allows to prevent a partial crystallization, thereby enabling a prompt crystallization in the next crystallization step.

The raw material compound to be employed in the present invention is a thermally decomposable metal compound.

The thermally decomposable metal compound employable in the present invention may be an alkyl metal compound, an alkoxy metal compound, an alkoxyalkyl metal compound, a diketone compound, an olefin compound or a halide. As the alkyl metal compound, there is preferred an alkyl metal compound that has an alkyl group containing up to 22 carbon atoms, such as methyl, ethyl, isopropyl, butyl, isobutyl, t-butyl, sec-butyl, pentyl, isopentyl, hexyl, octyl, dodecyl, or behenyl. Also as the alkoxy metal compound, there is preferred an alkoxy metal compound that has an alkoxyl group containing up to 22 carbon atoms, such as methoxy, ethoxy, propoxy, isopropoxy, butoxy, t-butoxy, sec-butoxy, hexyloxy, or dodecyloxy. Also as the alkoxyalkyl metal compound, there is preferred an alkoxyalkyl metal compound that has an alkoxyalkyl group such as methoxymethyl, methoxyethyl, ethoxymethyl, propoxymethyl or propoxybutyl.

Also as the diketone compound, there is preferably employed a metal compound having acetylacetone, 6-ethyl-2,2-dimethyl-2,5-decanedione (abbreviated as EDMDD), bis(dipivaloyl)methanate (abbreviated as thd) or the like as a substituent or a ligand. As the olefin compound, there is preferred a metal compound having, as a ligand, cyclopentadiene, methylcyclopentadiene, ethylcyclopentadiene, propylcyclopentadiene, cyclohexadiene, or cyclooctadiene. As the halide, there is preferred a metal halide such as chloride, bromide, fluoride or iodide.

These compounds may include same substituents or ligands, or may include plural different substituents or ligands.

The perovskite type oxide thin film obtained by the film forming method of the present invention is a thin film, adapted for use in a piezoelectric element or an electrostriction element. In the film forming method of the invention, the thin film is normally formed on a substrate. A substrate to be employed in the present invention preferably has a heat resistance of 600° C. or higher, and may be, for example, a Si substrate, a MgO substrate, an STO substrate, a SUS substrate or a Ti foil. In case of forming a thin film of a single-crystalline perovskite type oxide or a mono-oriented polycrystalline perovskite type oxide by the film forming method of the invention utilizing the MO-CVD process, the substrate is preferably a substrate having an epitaxial layer as an underlayer on a Si substrate. It is also preferred to utilize a SrTiO₃ single-crystalline substrate or a MgO single-crystalline substrate.

In the following, an oxide thin film element of the present invention will be explained.

The oxide thin film element of the present invention is featured in including a piezoelectric member, formed by a perovskite type oxide thin film formed by the film forming method of the present invention, and a pair of electrodes in contact with the piezoelectric member.

Now embodiments of the piezoelectric element of the present invention will be explained with reference to the accompanying drawings.

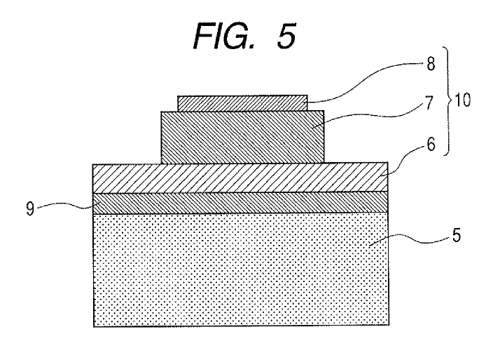

FIG. 5 is a schematic cross-sectional view of an embodiment of the oxide thin film element of the present invention. An oxide thin film element 10 of the present invention at least includes a first electrode film 6, a piezoelectric member 7 constituted of a perovskite type oxide thin film formed by the film forming method of the present invention, and a second electrode film 8. In the oxide thin film element of the embodiment shown in FIG. 5, the oxide thin film element 10 is shown to have a rectangular cross-sectional shape, but it may also have a trapezoidal or inverted trapezoidal shape. The oxide thin film element 10 of the present invention is formed on a substrate 5, but each of the first electrode film 6 and the second electrode film 8, constituting the oxide thin film element 10 of the invention, may be arbitrarily selected as the upper or lower electrode. This selection depends on the process of device formation, and the effects of the present invention can be attained in either. Also a buffer layer 9 may be provided between the substrate 5 and the first electrode film 6.

The oxide thin film element 10 of the present invention may be prepared, utilizing a substrate 5 or a substrate 5 provided with a buffer layer 9, prepared in advance. It can be prepared by forming a first electrode layer 6 on the substrate 5 or the substrate 5 provided with the buffer layer 9, prepared in advance, then forming thereon a perovskite type oxide thin film as a piezoelectric member 7 by the film forming method of the invention, and further forming a second electrode film 8.

The first electrode film (electrode) or the second electrode film (electrode) of the oxide thin film element of the present invention is preferably formed by a material, which has a satisfactory adhesion to the aforementioned piezoelectric member and has a high electroconductivity. More specifically, it is preferably formed by a material that can realize a specific resistivity of from 10⁻⁷ to 10⁻² Ω·cm in the upper or lower electrode film. Such material is generally a metal, and it is preferable to utilize, as the electrode material, a metal such as Au, Ag or Cu or a metal of Pt group such as Ru, Rh, Pd, Os, Ir or Pt. Also an alloy material such as a silver paste or a solder, containing the above-mentioned materials, has a high electroconductivity and may be employed advantageously. Also a conductive oxide material, such as IrO (iridum oxide), SRO (strontium ruthenite), ITO (conductive tin oxide) or BPO (barium plumbate) is preferable as an electrode material. Also the electrode film may have a single-layer structure or a multi-layered structure. For example, a structure such as Pt/Ti may be adopted in order to improve the adhesion to the substrate. Also the first electrode may be dispensed with when the substrate itself is conductive, for example in case of a Ti foil. The electrode film preferably has a film thickness of 20 nm or larger, and more preferably 100 nm or larger. Also the electrode film preferably has a film thickness of 1000 nm or less, preferably 400 nm or less. A film thickness of the electrode film of 20 nm or larger provides a sufficiently small resistance in the electrode film, and a film thickness of 1000 nm or less does not hinder the piezoelectric property of the oxide thin film element.

In the present invention, the electrode film is not restricted in the forming method, but an electrode film of 1000 nm or less may normally be prepared by a thin film forming process such as a sol-gel process, a hydrothermal synthesis, a gas deposition, or an electrophoretic process. It can also be prepared by a thin film forming process such as a sputtering, a chemical vapor deposition (also abbreviated as CVD), an MO-CVD process, an ion beam deposition, a molecular beam epitaxy, or a laser ablation. Since such thin film forming processes enable a mono-axial orientation and a mono-crystal formation in the electrode film by an epitaxial growth from the substrate or from the buffer layer, thus easily achieving a mono-axial orientation and a single-crystal formation in the piezoelectric member.

### EXAMPLES

Now the present invention will be explained by examples.

### Example 1

A perovskite type oxide thin film of (Bi, La) (Ti, Nd)O type oxide was prepared by an MO-CVD process.

[Raw materials]

Bi(CH₃)₃ was employed as the raw material for Bi, La(thd)₃ as the raw material for La, Nd(Ot-C₄H₉)₃ as the raw material for Nd, and Ti(i-C₃H₇O)₄ as the raw material for Ti.

[Producing process]

A Si substrate, having a thermal oxide film and bearing a Pt/TiO₂ electrode formed thereon, was employed as the substrate. The substrate was regulated at a temperature of 500° C., and the introducing amounts of the raw material gases were regulated under a supply of oxygen gas and nitrogen gas with a partial pressure regulated at 330 Pa.

The elements of the site A had valence numbers of Bi (trivalent) and La (trivalent) while the elements of the site B had valence numbers of Ti (tetravalent) and Nd (divalent). Therefore the elements were divided into a group I [Bi] and a group II [La, Ti, Nd], and the raw materials containing the elements belonging to such respective groups were supplied in respectively different steps to the substrate.

At first a first step was executed to supply the substrate with the Bi raw material for 7 seconds. Then the raw material supply was suspended for 10 seconds, and a thin film formed on the substrate was preliminarily heated at 500° C. which was the substrate temperature. Then the La raw material gas, the Ti raw material gas and the Nd raw material gas were prepared with partial pressures of oxygen gas and nitrogen gas respectively regulated at 330 Pa, and the raw materials for La, Ti and Nd were supplied to the substrate with a compositional ratio of 1:2:2. The supply time was 12 seconds, and this step constitutes a second step. Then, the raw material supply was suspended for 10 seconds, and a thin film formed on the substrate was preliminarily heated at 500° C. which was the substrate temperature. These steps were repeated for 80 minutes to obtain a crystalline thin film having a thickness of 300 nm. The obtained thin film was proven, in an analysis with an X-ray diffractometry apparatus (Philips MRD), as a perovskite type thin film having a composition of (Bi_{3.8}, La_{0.2})₄(Ti_{0.5}, Nd_{0.5})₃O₁₂. It was found that this thin film was a perovskite oxide thin film of a satisfactory quality, without a pyrochlore phase.

Also a residual polarization, measured with a ferroelectric measuring apparatus (FCE, manufactured by Toyo Technica Ltd.) and with an upper electrode of 100 μmΦ, showed a ferroelectricity as good as 25 μC/cm², and a thin film of satisfactory crystalliity could be reproducibly obtained in repeated film formations by this film forming method.

In case of forming a mono-crystal film or a mono-oriented film by the aforementioned method, there may be employed a Si substrate having an epitaxial layer thereon as an undercoat layer, a SrTiO₃ single-crystalline substrate, or a MgO single-crystalline substrate.

### Example 2

A perovskite type oxide thin film of (Sr, Bi)TaO type oxide was prepared by an MO-CVD process.

[Raw materials]

Sr(i-C₃H₇O)₂ was employed as the raw material for Sr, Bi(CH₃)₃(2-(CH₃)₂NCH₂C₆H₅ as the raw material for Bi, and Ta(i-C₄H₉O)₅ as the raw material for Ta.

[Producing process]

A Si (110) substrate, having a IrO₂ (110) thereon, was employed as the substrate. The substrate was regulated at a temperature of 700° C., and the partial pressures of the raw material gases were regulated under a supply of oxygen gas with a partial pressure regulated at 400 Pa and argon gas with a partial pressure regulated at 200 Pa.

The elements of the site A had valence numbers of Sr (divalent) and Bi (trivalent) while the element of the site B had a valence numbers Ta (pentavalent). Therefore the elements were divided into a group I [Bi, Sr] and a group II [Ta], and the raw materials containing the elements belonging to such respective groups were supplied in respectively different steps to the substrate.

At first a first step was executed to supply the substrate with the raw materials for Bi and Sr for 7 seconds. Then the raw material supply was suspended for 10 seconds, and a thin film formed on the substrate was preliminarily heated at 700° C. which was the substrate temperature. Then a second step of supplying the substrate with the Ta raw material for 8 seconds, under the regulation of the partial pressures of oxygen gas and argon gas and under the regulation of the partial pressure of the raw material gas, following by the aforementioned step of suspending the raw material supply for 10 seconds. These steps were repeated for 60 minutes to obtain a crystalline thin film having a thickness of 250 nm. The obtained thin film was analyzed and subjected to the measurement of residual polarization as in Example 1. The thin film was a perovskite type oxide thin film having a composition of (Bi₂O₂) (Sr_{0.8}Bi_{0.2})Ta₂O₇. It had a satisfactory residual polarization of 20 μC/cm².

### Example 3

Film formation was executed in the same conditions as in Example 2, except for employing a SrTiO₃ (111) single-crystalline substrate bearing a SrRuO₃ (111) epitaxial electrode as the substrate, to obtain a (Bi₂O₂) (Sr_{0.8}Bi_{0.2})Ta₂O₇ thin film. The obtained film was a (103) epitaxial film, with a satisfactory quality showing a residual polarization of 28 μC/cm².

### Comparative Example 1

In Example 1, the film formation was conducted, without dividing the raw material gases, but by supplying all the raw materials for Bi, La, Ti and Nd at the same time. The obtained film contained a pyrochlore phase and showed an unsatisfactory dielectric property of 5 μC/cm².

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2005-305814, filed Oct. 20, 2005, which is hereby incorporated by reference herein in its entirety.

What is claimed is:

1. A method of forming, on a substrate, a thin film of a perovskite type oxide in which at least either of a site A and a site B is constituted of plural elements and the plural elements in at least either site include elements different in valence number within such site, the method comprising steps of:
dividing the elements belonging to the site A and the site B in plural groups in such a manner that the elements different in valence number belong to a same group; and
supplying the substrate with raw materials containing the elements belonging to the respective groups in respectively different steps.

2. A film forming method according to claim 1, wherein the steps of supplying the substrate with the raw materials containing the elements belonging to such respective groups in respectively different steps are executed in repetition.

3. A film forming method according to claim 1, wherein the substrate is heated after the steps of supplying the substrate with the raw materials.

4. A film forming method according to claim 1, wherein the film formation is executed by any of a metalorganic chemical vapor deposition process, a sol-gel process, and a metal organic compound deposition process.

5. A thin film of a perovskite type oxide, formed on a substrate, in which at least either of a site A and a site B is constituted of plural elements and the plural elements in at least either site include elements different in valence number within such site, wherein the thin film is formed by a method of dividing the elements belonging to the site A and the site B in plural groups in such a manner that the elements different in valence number belong to a same group; and supplying the substrate with raw materials containing the elements belonging to such respective groups in respectively different steps.

6. A thin film of a perovskite type oxide according to claim 5, wherein the thin film has a thickness of from 50 nm to 10 μm.

7. An oxide thin film element comprising a piezoelectric member, including a thin film of a perovskite type oxide, formed on a substrate, in which at least either of a site A and a site B is constituted of plural elements and the plural elements in at least either site include elements different in valence number within such site, wherein the thin film is formed by a method of dividing the elements belonging to the site A and the site B in plural groups in such a manner that the elements different in valence number belong to a same group; and supplying the substrate with raw materials containing the elements belonging to such respective groups in respectively different steps, and a pair of electrodes in contact with the piezoelectric member.
